(19) United States
(12) Patent Application Publication
(10) Pub. No.: US 2022/0007517 A1
(43) Pub. Date: Jan. 6, 2022

(54) ELECTRONIC UNIT COMPRISING ELECTRONIC COMPONENTS AND AN ARRANGEMENT FOR PROTECTING SAME FROM PRESSURE

(71) Applicant: ZF Friedrichshafen AG, Friedrichshafen (DE)

(72) Inventor: Josef Loibl, Bad Abbach (DE)

(73) Assignee: ZF Friedrichshafen AG, Friedrichshafen (DE)

(21) Appl. No.: 17/291,374

(22) PCT Filed: Nov. 4, 2019
(86) PCT No.: PCT/EP2019/080012

§ 371 Date: May 5, 2021

(30) Foreign Application Priority Data
Nov. 5, 2018 (DE) 10 2018 218 783.5

(51) Int. Cl. H05K 3/28; H05K 5/00

(52) U.S. Cl. CPC H05K 3/284; H05K 5/0082; H05K 2203/1327; H05K 2203/1316; H05K 2201/10977

(57) ABSTRACT

An electronic unit may have a printed circuit board populated on a main surface of the printed circuit board with at least one electronic component coated with a coating element, where the at least one electronic component is embedded, and where there is a protective element that bears directly on the electronic component on a side facing away from the printed circuit board.

### RELATED APPLICATION

This application is a filing under 35 U.S.C. § 371 of International Patent Application PCT/EP2019/080012, filed Nov. 4, 2019, and claiming priority to German Patent Application 10 2018 218 783.5, filed Nov. 5, 2018. All applications listed in this paragraph are hereby incorporated by reference in their entireties.

### TECHNICAL FIELD

The present disclosure relates to an electronic unit comprising electronic components and an assembly for protecting them against pressure.

### BACKGROUND

Current serial applications for mechatronic control units comprise encapsulated electronics (e.g. a metal housing with glass passages) and a distribution of signals and currents via lead frames, wires, or flexible printed circuit boards. Electronic control units are constantly becoming increasingly less expensive while maintaining or increasing their scope of functions. This requires further development of existing designs, or the use of novel concepts. The connection technology used between individual components is of particular interest, because the vulnerability to dirt and vibrations increases as the electronic components become increasingly miniaturized. This is the case in particular in the field of automotive engineering, in which electronic components must function reliably, even under the most severe conditions.

An electronic unit containing a printed circuit board and numerous electronic components arranged on the printed circuit board is known from DE 10 2013 215 368. To protect it from environmental effects, the electronic unit is encapsulated, e.g. in a thermosetting plastic. The disadvantage with this is that high pressures are exerted on the electronic components during the coating process, which could damage them.

### BRIEF DESCRIPTION OF THE DRAWINGS

Certain features, aspects, and advantages of the disclosed embodiments are shown in the drawings accompanying this description. The drawings are briefly described below.

FIG. 1 shows a sectional view of a schematic illustration of an electronic unit in a first embodiment.

FIG. 2 shows a sectional view of a schematic illustration of an electronic unit in another embodiment.

FIG. 3 shows a sectional view of a schematic illustration of an electronic unit in another embodiment.

### DETAILED DESCRIPTION

In view of the above background, an object of the present embodiments is to create an electronic unit in which damage to the electronic components is prevented during the coating process.

An electronic unit is proposed that has a printed circuit board, populated on a main surface of the printed circuit board with at least one electronic component coated with a coating element, in which the at least one electronic component is embedded. According to certain aspects of the present disclosure, there is a protective element that bears directly on a side of the electronic component facing away from the printed circuit board.

A protective element is understood to be an element that protects against mechanical effects at a side of an electronic component facing away from the printed circuit board. A side of a component facing away from the printed circuit board is a side of the electronic component that does not lie opposite a main surface of the printed circuit board. In particular, a protective element is a robust element that does not bend when subjected to pressure on one of its surfaces, i.e. does not become deformed. This protective element ensures that the coating element cannot exert pressure on the electronic component. Any pressure exerted by the coating element toward the electronic component is therefore absorbed and compensated for by the protective element.

Electronic components are those components that are used in a mechatronic control unit, in particular a transmission control unit. In particular, electronic components are those components in which one or more parts of the component are encapsulated in a housing. One example of such an electronic component is an electrolytic capacitor. An electrolytic capacitor is composed of an aluminum housing, in which a sleeve soaked in electrolytic fluid is located, insulated against the outer wall. The electrical connections pass through a seal on the lower surface of the component. The sleeve is substantially composed of an anode film, a cathode film, and a spacer soaked in electrolytes lying between them.

A coating element herein is a cured casting compound, e.g. thermosetting plastic. This casting compound is applied to at least partial of the electronic unit using a coating tool. The casting compound is applied to at least part of the electronic unit at high pressure, up to 50 bar. As a result, the casting compound encompasses the electronic components and/or the printed circuit board in the electronic unit. After the casting compound has cured, the coating element is formed.

In one embodiment, the protective element can form a cap, and bear on numerous sides of the electronic component. This ensures an optimal absorption of the pressure acting on the electronic component by the protective element. This also ensures that the electronic component is not subjected to lateral pressures that could damage the electronic component. In particular, damage to the electronic components when applying the casting compound to the printed circuit board and the electronic components under high pressure is prevented during a coating process.

In another embodiment, the protective element can form a plate, and bear on the upper surface of the electronic component. The protective element is in the form of a pad in this case, which provides optimal coverage for the upper surface of the component to which it is applied. As a result, any pressure to the upper surface of the component during the coating process is optimally absorbed by the pad, preventing damage to the component. The pad can be made of metal or plastic.

In another embodiment, the protective element can be made of a cured adhesive material. This adhesive material moistens and hardens the upper surface of the electronic component. The adhesive material is applied and/or distributed evenly on the surface of the electronic component. The adhesive material can be cured by applying heat and UV light.

The protective element can also be made of metal or plastic, wherein the protective element can be glued to the electronic component. The protective element can be designed to protect one or more sides of the electronic component from external pressures. The protective element can be a single piece, or it can comprise multiple parts.

In another embodiment, filler can be placed between the printed circuit board and the side of the electronic component facing the printed circuit board. This enables a mechanical connection and sealing of the lower surface, i.e. the side of the component facing the printed circuit board, to the printed circuit board. The filler material can be the same adhesive material that can also be used as the protective element for an electronic component, in particular an epoxy.

Another aspect includes a transmission control for motor vehicles that contains an electronic unit.

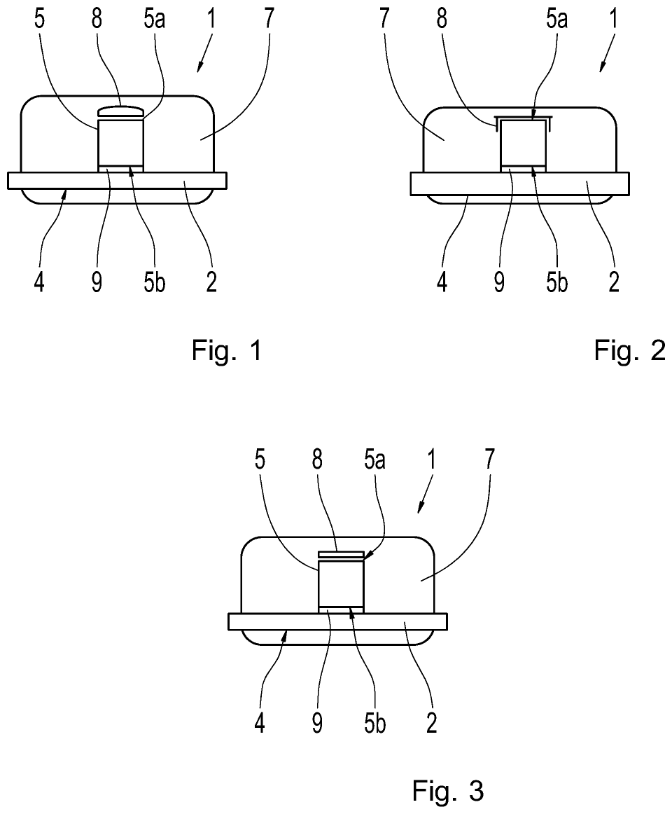

FIG. 1 shows a schematic illustration of a first embodiment of an electronic unit 1. The electronic unit 1 comprises a printed circuit board 2, and an electronic component 5 placed on the printed circuit board 2. By way of example, an electronic component 5 is placed on the upper surface 3 of the printed circuit board 2. It is also possible to populate the lower surface 4 with further electronic components (not shown). The electronic unit 1 also has a coating element 7. The coating element 7 encompasses the electronic component 5 on the upper surface 4 of the printed circuit board 2. The coating element 7 also encompasses portions of the upper and lower surfaces 3, 4 of the printed circuit board 2. This makes it possible to protect, e.g. conductor paths (not shown) on the upper or lower surfaces 3, 4 of the printed circuit board 2 from environmental effects.

The coating element 7 is applied to the printed circuit board 2 or the electronic component 5 by means of a coating process. The coating material is applied at high pressure to the printed circuit board 2 and/or the components 5 with a coating tool in this coating process. As explained above, certain aspects of the present disclosure are not used, this process can result in damages to the electronic component 5.

The electronic component 5 has electrical connections (not shown) on its lower surface 5b, with which it is attached to the printed circuit board 2. A protective element is placed on the upper surface 5a of the electronic component 5. By way of example, protective element 8 is made of an adhesive material, e.g. epoxy. The protective element 8 is attached to the upper surface 5a of the component 5. As a result, there are no high pressure effects to the upper surface 5a of the component 5 during the coating process, thus preventing damage to the electronic component. It is also possible to place more protective elements 8 on one or more sides of the component 5.

A filler 9 is inserted between the lower surface 5b of the electronic component 5 and the upper surface 3 of the printed circuit board 2. This filler 9, e.g. epoxy, seals and secures the electronic connections (not shown) on the component 5 to the printed circuit board 2.

FIG. 2 shows a schematic illustration of another embodiment of an electronic unit 1. This embodiment is substantially the same as the first embodiment. This embodiment differs from the first in particular with regard to the protective element 8. The protective element 8 forms a cap, and covers both the upper surface 5a of the component 5 and the lateral surfaces of the component 5. In particular, the protective element 8 is robust, such that it does not become deformed by the pressure exerted thereon during the coating process.

FIG. 3 shows a schematic illustration of another embodiment of an electronic unit 1. This embodiment is substantially the same as the first embodiment. This embodiment differs from the first in particular with regard to the design of the protective element 8. The protective element 8 forms a plate, and covers the upper surface 5a of the electronic component 5. The protective element 8 can be glued to the upper surface 5a of the component 5.

### REFERENCE SYMBOLS

1 electronic unit
2 printed circuit board
3 upper surface of the printed circuit board
4 lower surface of the printed circuit board
5 electronic component
5a upper surface of the electronic component
5b lower surface of the electronic component
7 coating element
8 protective element
9 filler

1. An electronic unit, comprising:
a printed circuit board located on a main surface of the electronic unit,
wherein the printed circuit board includes at least one electronic component coated with a coating element,
wherein the at least one electronic component is embedded; and
a protective element that directly contacts the electronic component on a side of the electronic component facing away from the printed circuit board.

2. The electronic unit according to claim 1, wherein the protective element forms a cap, and wherein the protective element contacts a plurality of surfaces of the electronic component.

3. The electronic unit according to claim 1, wherein the protective element forms a plate, and wherein the protective element contacts an upper surface of the electronic component.

4. The electronic unit according to any of claim 1, wherein the protective element comprises a cured adhesive material.

5. The electronic unit according to claim 1, wherein the protective element is made of metal or plastic.

6. The electronic unit according to claim 5, wherein the protective element is glued to the electronic component.

7. The electronic unit according to claim 1, wherein a filler is placed between the printed circuit board and the side of the electronic component facing the printed circuit board.

8. A transmission control for motor vehicles that has an electronic component according to claim 1.

9. An electronic unit, comprising:
a printed circuit board located on a main surface of the electronic unit,
wherein the printed circuit board includes at least one electronic component coated with a coating element,
wherein the at least one electronic component is embedded; and
a plate that directly contacts an upper surface of the electronic component on a side of the electronic component facing away from the printed circuit board.

10. The electronic unit according to any of claim 9, wherein the plate comprises a cured adhesive material.

11. The electronic unit according to claim 9, wherein the plate is made of metal or plastic.

12. The electronic unit according to claim 12, wherein the plate is glued to the electronic component.

13. The electronic unit according to claim 9, wherein a filler is placed between the printed circuit board and the side of the electronic component facing the printed circuit board.

14. An electronic unit, comprising:
a printed circuit board located on a main surface of the electronic unit,
wherein the printed circuit board includes at least one electronic component coated with a coating element,
wherein the at least one electronic component is embedded; and
a cap that directly contacts a plurality of surfaces of the electronic component, including at least one surface on a side of the electronic component facing away from the printed circuit board.

15. The electronic unit according to any of claim 14, wherein the cap comprises a cured adhesive material.

16. The electronic unit according to claim 14, wherein the cap is made of metal or plastic.

17. The electronic unit according to claim 16, wherein the cap is glued to the electronic component.

18. The electronic unit according to claim 14, wherein a filler is placed between the printed circuit board and the side of the electronic component facing the printed circuit board.
